(19) United States
(12) Patent Application Publication
(10) Pub. No.: US 2026/0058627 A1
(43) Pub. Date: Feb. 26, 2026

(54) FILTER DEVICE

(71) Applicant: Murata Manufacturing Co., Ltd., Nagaokakyo-shi (JP)

(72) Inventor: Keisuke OGAWA, Nagaokakyo-shi (JP)

(21) Appl. No.: 19/262,535

(22) Filed: Jul. 8, 2025

(30) Foreign Application Priority Data
Aug. 26, 2024 (JP) 2024-144248

(51) Int. Cl. H03H 7/01; H03H 1/00; H04B 1/04

(52) U.S. Cl. CPC H03H 7/0115; H04B 1/04; H03H 1/00; H03H 2001/0085

(57) ABSTRACT

A filter device includes a multilayer body including dielectric layers, and an LC resonator including an inductor and a capacitor to transmit a signal from an input terminal to an output terminal. The LC resonator includes plate electrodes on dielectric layers different from each other and connected by a via. The plate electrodes define and function as the inductor. The plate electrodes overlap at least partially in a direction of lamination of the multilayer body. Each of the plate electrodes includes an extending portion extending in an x axis direction, and an extending portion extending in a y axis direction. An area of the extending portion of one plate electrode is smaller than an area of the other extending portion.

### CROSS REFERENCE TO RELATED APPLICATIONS

This application claims the benefit of priority to Japanese Patent Application No. 2024-144248 filed on Aug. 26, 2024. The entire contents of this application are hereby incorporated herein by reference.

### BACKGROUND OF THE INVENTION

### 1. Field of the Invention

The present disclosure relates to filter devices.

### 2. Description of the Related Art

International Publication No. 2017/014058 discloses a multilayer LC filter (a filter device) including multiple tiers of resonators. In International Publication No. 2017/014058, electrodes defining inductors have a two-layered structure by stacking and arranging plate electrodes parallel in a direction of lamination. By providing the above-described configuration, a Q factor of the filter device is improved by reducing a resistance value of a current pathway.

In a case of laminating and pressure bonding multiple dielectric layers in the filter device, there is a possibility of causing lamination misalignment in which positions of the respective dielectric layers are misaligned in an in-plane direction at pressure bonding surfaces thereof. An inside diameter of a coil in the inductors overlapping in a direction of lamination varies in the case where the lamination misalignment occurs in the electrodes that define the inductors. Accordingly, an inductance value may be changed from a designed value in some cases. Such a change in inductance value may affect filter characteristics including deviations of a pass band width, a center frequency, and the like of the filter.

### SUMMARY OF THE INVENTION

Example embodiments of the present invention provide filter devices each with reduced changes in filter characteristics due to lamination misalignment.

A filter device according to an example embodiment of the present invention includes a multilayer body including a plurality of dielectric layers, an input terminal and an output terminal on an outer surface of the multilayer body, and an LC resonator including an inductor and a capacitor and configured to transmit a signal from the input terminal to the output terminal. The LC resonator includes a first plate electrode and a second plate electrode on dielectric layers of the plurality of dielectric layers different from each other and connected to each other by via. The first plate electrode and the second plate electrode define and function as the inductor. The first plate electrode and the second plate electrode overlap at least partially in a plan view in a direction of lamination of the multilayer body. The multilayer body has a rectangular or substantially rectangular shape including a long side and a short side in the plan view in the direction of lamination. The first plate electrode includes a first extending portion extending in a first direction along a direction of the long side of the multilayer body, and a second extending portion extending in a second direction along a direction of the short side of the multilayer body. The second plate electrode includes a third extending portion extending in the first direction, and a fourth extending portion extending in the second direction. An area of the first extending portion is smaller than an area of the third extending portion.

A filter device according to an example embodiment of the present invention is configured such that the area of the first extending portion is smaller than the area of the third extending portion. In the case where the first plate electrode and the second plate electrode have the same or substantially the same shape, a change in area at the overlapping portion of the two plate electrodes that overlap in the direction of lamination is larger in the case of the occurrence of lamination misalignment in the short side direction than that in the case of the occurrence of lamination misalignment in the long side direction. Accordingly, a change in inside diameter of a coil defined by the electrodes defining and functioning as the inductor is reduced or prevented by setting the area of the first extending portion in the long side direction to be smaller than the area of the third extending portion. Thus, it is possible to reduce or prevent changes in filter characteristics even in the case of the occurrence of lamination misalignment that may lead to displacement of positions of the first plate electrode and the second plate electrode.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a block diagram of a communication apparatus including a high frequency front end circuit to which a filter device according to Example Embodiment 1 of the present invention is applied.

FIG. 2 is an equivalent circuit diagram of the filter device according to Example Embodiment 1 of the present invention.

FIG. 3 is an outline perspective view of the filter device according to Example Embodiment 1 of the present invention.

FIG. 4 is an exploded perspective view showing an example of a lamination structure of the filter device according to Example Embodiment 1 of the present invention.

FIGS. 5A to 5D are diagrams for explaining electrode configurations of Example Embodiment 1 of the present invention.

FIG. 6 is an exploded perspective view showing an example of a lamination structure of a filter device of Comparative Example.

FIG. 7 illustrates diagrams for explaining changes in characteristics of Example Embodiment 1 of the present invention and Comparative Example.

FIG. 8 is an exploded perspective view showing an example of a lamination structure of a filter device according to Example Embodiment 2 of the present invention.

FIGS. 9A to 9C are diagrams for explaining electrode configurations of Example Embodiment 2 of the present invention.

FIG. 10 is a diagram for explaining electrode configurations of Modified Example 1 of an example embodiment of the present invention.

FIGS. 11A to 11C are diagrams for explaining electrode configurations of Modified Example 2 of an example embodiment of the present invention.

### DETAILED DESCRIPTION OF THE EXAMPLE EMBODIMENTS

Example embodiments of the present invention will be described below in detail with reference to the drawings. The same or equivalent portions in the drawings will be denoted by the same reference signs and explanations thereof will not be repeated.

### Example Embodiment 1

### Basic Configuration of Communication Apparatus

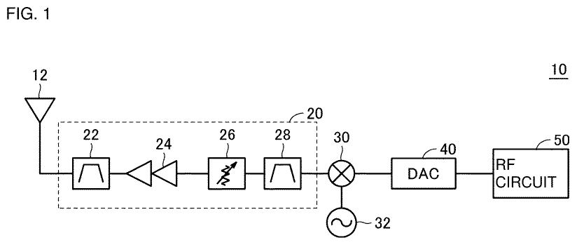

FIG. 1 is a block diagram of a communication apparatus 10 including a high frequency front end circuit 20 to which a filter device 100 according to Example Embodiment 1 of the present invention is applied. The communication apparatus 10 is a portable terminal as typified by a smartphone, or a cellular phone base station, for example.

Referring to FIG. 1, the communication apparatus 10 includes an antenna 12, the high frequency front end circuit 20, a mixer 30, a local oscillator 32, a D/A converter (DAC) 40, and an RF circuit 50. The high frequency front end circuit 20 includes band pass filters 22 and 28, an amplifier 24, and an attenuator 26. Here, FIG. 1 will describe a case where the high frequency front end circuit 20 includes a transmission circuit that transmits a high frequency signal from the antenna 12. However, the high frequency front end circuit 20 may include a reception circuit that receives a high frequency signal via the antenna 12.

The communication apparatus 10 up-converts a transmission signal transferred from the RF circuit 50 into the high frequency signal, and emits the high frequency signal from the antenna 12. A modulated digital signal being the transmission signal outputted from the RF circuit 50 is converted into an analog signal by the D/A converter 40. The mixer 30 mixes the transmission signal, which is converted from the digital signal into the analog signal by the D/A converter 40, with an oscillation signal from the local oscillator 32, thus up-converting the transmission signal into the high frequency signal. The band pass filter 28 removes unnecessary waves generated by up-converting and extracts the transmission signal only in a desired frequency band. The attenuator 26 adjusts an intensity of the transmission signal. The amplifier 24 subjects the transmission signal having passed through the attenuator 26 to power amplification up to a predetermined level. The band pass filter 22 removes unnecessary waves generated in the amplification process and allows passage of a signal component only in a frequency band determined by communication standards. The transmission signal having passed through the band pass filter 22 is emitted from the antenna 12.

Filter devices according to example embodiments of the present invention can be used as the band pass filters 22 and 28 in the above-described communication apparatus 10.

### Configuration of Filter Device

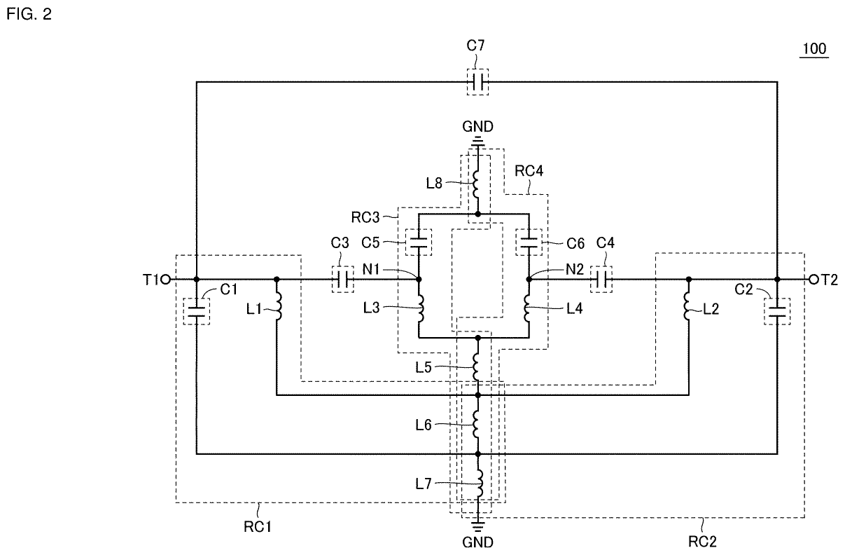

Next, a detailed configuration of the filter device 100 of the present example embodiment will be described with reference to FIGS. 2 to 4. In the following description, a circuit installed inside the filter device 100 may also be referred to as a “filter circuit” as appropriate.

### 1 Equivalent Circuit

FIG. 2 is an equivalent circuit diagram of the filter device 100 of Example Embodiment 1. Referring to FIG. 2, the filter device 100 includes an input terminal T1, an output terminal T2, a ground terminal GND, resonators RC1 to RC4, and capacitors C3, C4, and C7. The resonators RC1 to RC4 are LC resonators each of which includes inductors and a capacitor.

The resonator RC1 includes inductors L1, L6, and L7 connected in series between the input terminal T1 and the ground terminal GND, and a capacitor C1 connected in parallel to the inductors L1 and L6 that are connected in series.

The resonator RC2 includes inductors L2, L6, and L7 connected in series between the output terminal T2 and the ground terminal GND, and a capacitor C2 connected in parallel to the inductors L2 and L6 that are connected in series.

The capacitor C7 is connected between the input terminal T1 and the output terminal T2. The resonator RC1 is field-coupled to the resonator RC2 by capacitor C7.

The resonator RC3 includes inductors L3, L5, L6, L7, and L8, and a capacitor C5. In the resonator RC3, one end of the capacitor C5 is connected to the ground terminal GND with the inductor L8 interposed therebetween. Meanwhile, another end of the capacitor C5 is connected to the ground terminal GND with the inductors L3, L5, L6, and L7 connected in series and interposed therebetween. In the resonator RC3, the inductors L3, L5, L6, and L7, the capacitor C5, and the inductor L8 are connected in parallel.

The resonator RC4 includes inductors L4, L5, L6, L7, and L8, and a capacitor C6. In the resonator RC4, one end of the capacitor C6 is connected to the ground terminal GND with the inductor L8 interposed therebetween. Meanwhile, another end of the capacitor C6 is connected to the ground terminal GND with the inductors L4, L5, L6, and L7 connected in series and interposed therebetween. The resonator RC4 shares the inductors L5, L6, L7, and L8 with the resonator RC3. In the resonator RC4, the inductors L4, L5, L6, and L7 the capacitor C6, and the inductor L8 are connected in parallel.

The capacitor C3 is connected between the input terminal T1 and a connection node N1 that is located between the capacitor C5 and the inductor L3. The resonator RC1 is field-coupled to the resonator RC3 by capacitor C3. The capacitor C4 is connected between the output terminal T2 and a connection node N2 that is located between the capacitor C6 and the inductor L4. The resonator RC2 is field-coupled to the resonator RC4 by capacitor C4. Here, the inductor L6 and the inductor L7 are shared by the resonators RC1 to RC4.

The respective resonators are coupled to one another by magnetic coupling. The filter device 100 has a configuration in which four tiers of the resonators being magnetically coupled to one another are disposed between the input terminal T1 and the output terminal T2. By adjusting resonant frequencies of the respective resonators, the filter device 100 defines and functions as the band pass filter that allows passage of a signal in a desired frequency band.

### 2 Detailed Structure

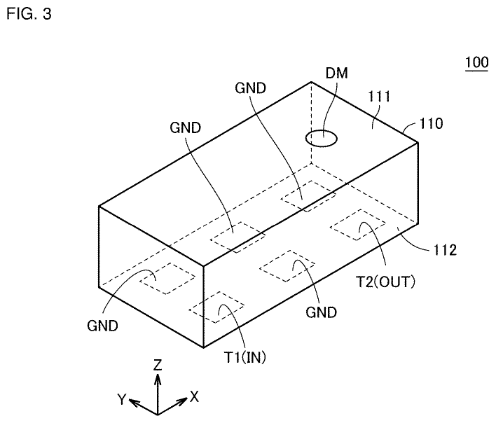

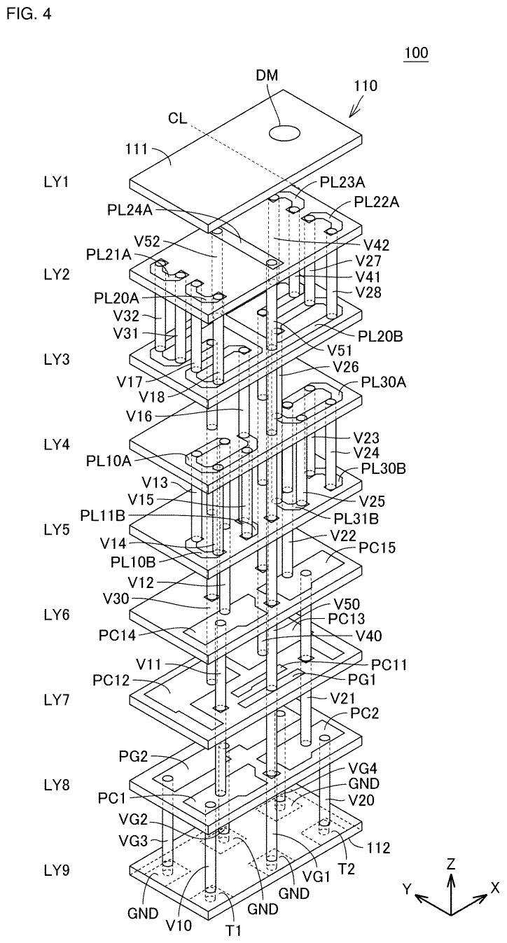

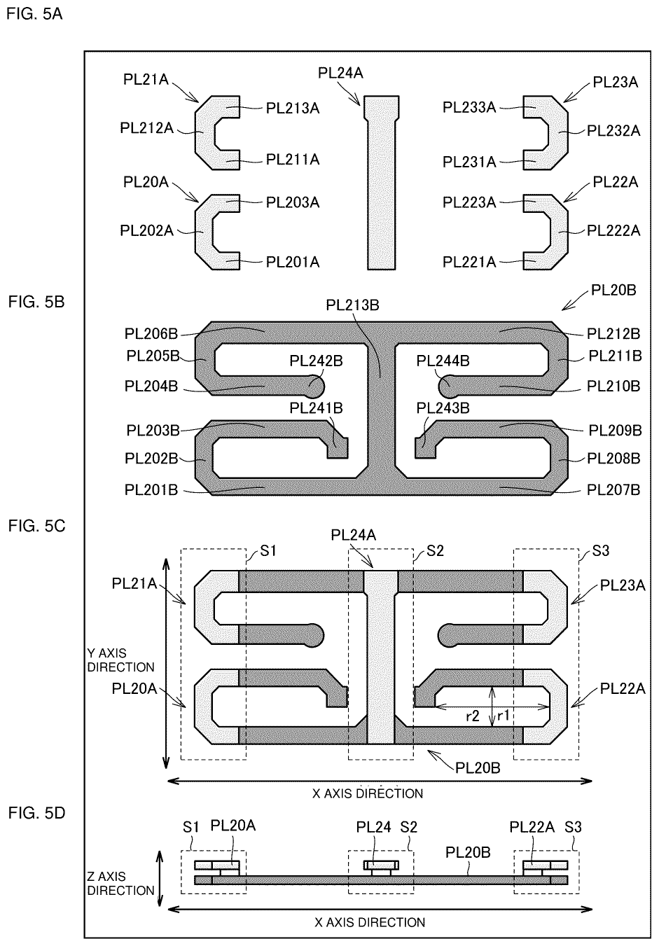

Next, a structure of the filter device 100 will be described with reference to FIGS. 3 to 5D. FIG. 3 is an outline perspective view of the filter device 100 of Example Embodiment 1. FIG. 4 is an exploded perspective view showing an example of a lamination structure of the filter device 100 of Example Embodiment 1. FIGS. 5A to 5D are diagrams for explaining electrode forms of Example Embodiment 1.

Referring to FIG. 3 and FIG. 4, the filter device 100 includes multiple dielectric layers LY1 to LY9 laminated in a direction of lamination, and a body 110 having a rectangular parallelepiped shape or a substantially rectangular parallelepiped shape as a whole. The dielectric layers LY1 to LY9 are each made a ceramic such as a low temperature co-fired ceramic (LTCC) or a resin, for example. Inductors and capacitors of LC parallel resonators are provided inside the body 110 by multiple electrodes provided to the respective dielectric layers and multiple vias provided between the dielectric layers. The “vias” in the present specification represent conductors provided in different dielectric layers in order to connect electrodes provided to the dielectric layers. Each via is made of conductive paste, plating, and/or a metal pin, for example.

In the following description, the direction of lamination of the dielectric layers LY1 to LY9 in the body 110 will be defined as “z axis direction”, a direction being perpendicular or substantially perpendicular to the z axis direction and extending along a long side of the body 110 will be defined as “x axis direction”, and a direction extending along a short side of the body 110 will be defined as “y axis direction”. Meanwhile, in the following description, a positive direction of the z axis in each drawing may be referred to as an upper side while a negative direction thereof may be referred to as a lower side as appropriate. In the meantime, the x axis direction along the direction of the long side of the multilayer body corresponds to a “first direction” of the present disclosure while the y axis direction along the direction of the short side of the multilayer body corresponds to a “second direction” of the present disclosure.

A directionality mark DM to specify a direction of the filter device 100 is provided at an upper surface 111 (the dielectric layer LY1) of the body 110. External terminals (the input terminal T1, the output terminal T2, and the ground terminals GND) to connect the filter device 100 to external equipment are provided at a lower surface 112 (the dielectric layer LY9) of the body 110 being an outer surface of the multilayer body. The input terminal T1, the output terminal T2, and the ground terminals GND each have a flat plate shape, which are land grid array (LGA) terminals that are regularly provided on the lower surface 112 of the body 110. As shown in FIG. 4, respective elements in the multilayer body of the filter device 100 are disposed line-symmetrically about an imaginary line CL.

As has been described with reference to FIG. 2, the filter device 100 is provided with the four-tier configuration including the resonators RC1 to RC4 that are the LC parallel resonators. To be more precise, the resonator RC1 includes vias V11, V12, V13, V14, V15, V16, V17, V18, V50, and VG1, capacitor electrodes PC1 and PC14, a ground electrode PG1, and plate electrodes PL10A, PL10B, PL11B, PL20A, and PL20B. The resonator RC2 includes vias V21, V22, V23, V24, V25, V26, V27, V28, V50, and VG1, capacitor electrodes PC2 and PC15, the ground electrode PG1, and plate electrodes PL30A, PL30B, PL31B, PL22A, and PL20B.

The resonator RC3 includes vias V30, V31, V32, V50, V51, V52, VG1, VG2, VG3, and VG4, a ground electrode PG2, a capacitor electrode PC12, and plate electrodes PL21A, PL24A, and PL20B. The resonator RC4 includes vias V40, V41, V42, V50, V51, V52, VG1, VG2, VG3, and VG4, a ground electrode PG2, a capacitor electrode PC13, and plate electrodes PL23A, PL24A, and PL20B.

The multilayer body of the filter device 100 has a rectangular or substantially rectangular shape including a long side and a short side in plan view in the direction of lamination. Electrode configurations to be provided on the respective dielectric layers will specifically be described. First, the electrode configurations of the capacitors will be described. Each of the capacitor electrodes PC1 and PC2 and the ground electrode PG2 provided on the dielectric layer LY8 is an electrode with a rectangular or substantially rectangular shape that extends in the x axis direction.

Each of the capacitor electrodes PC12 and PC13 provided on the dielectric layer LY7 is an L-shaped or substantially L-shaped electrode that extends in the x axis direction and the y axis direction. Each of a capacitor electrode PC11 and the ground electrode PG1 provided on the dielectric layer LY7 is an electrode with a rectangular or substantially rectangular shape that extends in the x axis direction. Each of the capacitor electrodes PC14 and PC 15 provided ln the dielectric layer LY6 is an electrode with a rectangular or substantially rectangular shape that extends in the x axis direction.

Next, the electrode configurations of the inductors will be described. Each of the plate electrodes PL10B, PL11B, PL30B, and PL31B provided the dielectric layer LY5 is a belt-shaped electrode with a C-shaped or substantially C-shaped wiring pattern. Each of the plate electrodes PL10A and PL30A provided on the dielectric layer LY4 is a belt-shaped electrode wound about the z axis and substantially has a J shape, a U shape, or a C shape, for example.

The plate electrodes PL20A, PL21A, PL22A, PL23A, and PL24A being provided on the dielectric layer LY2 and each corresponding to the first plate electrode, and the plate electrode PL20B being provided on the dielectric layer LY3 and corresponding to the second plate electrode will be described in detail with reference to FIGS. 5A to 5D. FIG. 5A is a diagram of the plate electrodes PL20A, PL21A, PL22A, PL23A, and PL24A on the dielectric layer LY2 in plan view in the z axis direction. FIG. 5B is a diagram of the plate electrode PL20B on the dielectric layer LY3 in plan view in the z axis direction.

FIG. 5C is a diagram of the dielectric layer LY2 and the dielectric layer LY3 in plan view in the z axis direction. FIG. 5D is a diagram of the dielectric layer LY2 and the dielectric layer LY3 in plan view in the y axis direction. Regions S1, S2, and S3 surrounded by dashed lines in FIG. 5C and FIG. 5D indicate electrode portions overlapping in the direction of lamination. As described above, the plate electrodes are disposed so as to overlap in the direction of lamination in the regions S1, S2, and S3, and are arranged in parallel or substantially in parallel by being connected with the vias. Thus, a cross-sectional area of a current pathway of the inductor can be increased. A resistance component is reduced and a loss due to a current is diminished as a consequence of the increase in cross-sectional area of the current pathway of the inductor, such that a Q factor can be improved.

As shown in FIG. 5A, the plate electrode PL20A includes extending portions PL201A and PL203A that extend in the x axis direction and correspond to a first portion and a second portion of a first extending portion, respectively, and an extending portion PL202A that extends in the y axis direction and corresponds to a second extending portion. An end portion in a negative direction of the x axis of the extending portion PL201A is connected to one end portion of PL202A. An end portion in the negative direction of the x axis of PL203A is connected to another end portion of PL202A. The plate electrode PL21A includes extending portions PL211A and PL213A that extend in the x axis direction, and an extending portion PL212A that extends in the y axis direction. An end portion in the negative direction of the x axis of the extending portion PL211A is connected to one end portion of PL212A. An end portion in the negative direction of the x axis of PL213A is connected to another end portion of PL212A.

The plate electrode PL22A includes extending portions PL221A and PL223A that extend in the x axis direction, and an extending portion PL222A that extends in the y axis direction. An end portion in a positive direction of the x axis of the extending portion PL221A is connected to one end portion of PL222A. An end portion in the positive direction of the x axis of PL223A is connected to another end portion of PL222A. The plate electrode PL23A includes extending portions PL231A and PL233A that extend in the x axis direction, and an extending portion PL232A that extends in the y axis direction. An end portion in the positive direction of the x axis of the extending portion PL231A is connected to one end portion of PL232A. An end portion in the positive direction of the x axis of PL233A is connected to another end portion of PL232A.

As shown in FIG. 5B, the plate electrode PL20B includes an extending portion PL213B that extends in the y axis direction. An extending portion PL201B extends in the negative direction of the x axis from one end of the extending portion PL213B, and PL207B extends in the positive direction of the x axis therefrom. Meanwhile, an extending portion PL206B extends in the negative direction of the x axis from another end of the extending portion PL213B, and PL212B extends in the positive direction of the x axis therefrom.

An end portion in the negative direction of the x axis of the extending portion PL201B corresponding to a first portion of a third extending portion is connected to one end of an extending portion PL202B, which extends in the y axis direction and corresponds to a fourth extending portion. Another end of the extending portion PL202B is connected to an end portion in the negative direction of x axis of an extending portion PL203B, which extends in the x axis direction and corresponds to a second portion of the third extending portion. An end portion PL241B in the positive direction of the x axis of the extending portion PL203B is an open end. An end portion in the positive direction of the x axis of the extending portion PL207B is connected to one end of an extending portion PL208B that extends in the y axis direction. Another end of the extending portion PL208B is connected to an end portion in the positive direction of the x axis of an extending portion PL209B that extends in the x axis direction. An end portion PL243B in the negative direction of the x axis of the extending portion PL209B is an open end.

An end portion in the negative direction of the x axis of the extending portion PL206B is connected to one end of an extending portion PL205B that extends in the y axis direction. Another end of the extending portion PL205B is connected to an end portion in the negative direction of the x axis of an extending portion PL204B that extends in the x axis direction. An end portion PL242B in the positive direction of the x axis of the extending portion PL204B is an open end. An end portion in the positive direction of the x axis of the extending portion PL212B is connected to one end of an extending portion PL211B that extends in the y axis direction. Another end of the extending portion PL211B is connected to an end portion in the positive direction of the x axis of an extending portion PL210B that extends in the x axis direction. An end portion PL244B in the negative direction of the x axis of the extending portion PL210B is an open end.

The plate electrode PL20B includes the extending portions PL201B to PL203B, the extending portions PL204B to PL206B, the extending portions PL207B to PL209B, and the extending portions PL210B to PL212B. The plate electrode PL20B is configured such that four annular belt-shaped electrodes include a winding axis in the z axis direction, and has a line-symmetric shape which is symmetric about the extending portion PL213B.

As shown in FIGS. 5A to 5D, the plate electrode PL20A is provided in the region S1 so as to overlap the extending portions PL201B, PL202B, and PL203B of the plate electrode PL20B in the direction of lamination and is connected thereto by vias. The plate electrode PL21A is provided in the region S1 so as to overlap the extending portions PL204B, PL205B, and PL206B of the plate electrode PL20B in the direction of lamination and is connected thereto by vias.

The plate electrode PL24A is provided in the region S2 so as to overlap the extending portion PL213B of the plate electrode PL20B in the direction of lamination and is connected thereto by vias. The plate electrode PL22A is provided in the region S3 so as to overlap the extending portions PL207B, PL208B, and PL209B of the plate electrode PL20B in the direction of lamination and is connected thereto by vias. The plate electrode PL23A is provided in the region S3 so as to overlap the extending portions PL210B, PL211B, and PL212B of the plate electrode PL20B in the direction of lamination and is connected thereto by vias.

Meanwhile, in the plate electrode PL20B, a distance in the y axis direction between the extending portion 207B and the extending portion 209B will be defined as r1 while a distance in the x axis direction between the end portion PL243B and the extending portion 208B will be defined as r2 as shown in FIG. 5C. In this case, the plate electrode PL20B is configured such that the distance r2 on an inner side of the annular belt-shaped electrode is longer than the distance r1 on the inner side of the annular belt-shaped electrode. This relationship similarly applies to the remaining three annular belt-shaped electrode portions of the plate electrode PL20B.

Here, regarding the plate electrode PL20A and the plate electrode PL20B overlapping in the direction of lamination, a length in the x axis direction of the extending portion PL201A is smaller than a length in the x axis direction of the extending portion PL201B. The length of each extending portion is equivalent to a length of a portion of the electrode in each plate electrode extending in the x axis direction, which does not include a length of the electrode in a tapered shape at a corner portion of each electrode. In the meantime, to described this in another way in terms of the area, the area of the extending portion PL201A is smaller than the area of the extending portion PL201B. The area of the extending portion is equivalent to a product of the length of each extending portion and an electrode width in the y axis direction of each extending portion. The above-described relationship is the same or substantially the same as a relationship between the extending portion PL203A and the extending portion PL203B, a relationship between the extending portion PL211A and the extending portion PL204B, a relationship between the extending portion PL213A and the extending portion PL206B, a relationship between the extending portion PL221A and the extending portion PL207B, a relationship between the extending portion PL223A and the extending portion PL209B, a relationship between the extending portion PL231A and the extending portion PL210B, and a relationship between the extending portion PL233A and the extending portion PL212B as well.

Back to FIG. 4, a description will be provided of connecting relationships of the respective elements of the multilayer body. The input terminal T1 is connected to the capacitor electrode PC1 provided the dielectric layer LY8 by a via V10. The capacitor electrode PC1 is connected to the capacitor electrode PC14 provided on the dielectric layer LY6 by the via V11. The capacitor electrode PC14 is connected to one end of the plate electrode PL10A provided on the dielectric layer LY4 by the via V12.

Another end of the plate electrode PL10A is connected to the end portion PL241B of the plate electrode PL20B and to one end of the plate electrode PL11B by the via V16. The vias V13, V14, and V15 are sequentially connected from one end to another end along a line of the plate electrode PL10A. The via V13 is connected to one end of PLIOB, and the via V14 is connected to another end of PLIOB. The via V15 is connected to another end of the plate electrode PL11B.

The via V17 is connected to one end of the plate electrode PL20A. The via V18 is connected to another end of the plate electrode PL20A. The vias V17 and V18 are sequentially connected along a line of the plate electrode PL20B.

The plate electrodes PL10B and PL11B are disposed so as to overlap the plate electrode PL10A in plan view in the direction of lamination. The plate electrode PL20A is disposed so as to overlap the plate electrode PL20B in plan view in the direction of lamination. The plate electrode PL20B is connected to the ground electrode PG1 provided on the dielectric layer LY7 by the via V50. The ground electrode PG1 is connected to the ground terminal GND provided on the dielectric layer LY9 by the via VG1.

The inductor L1 in FIG. 2 includes the vias V11, V12, V13, V14, V15, V16, V17, and V18, and the plate electrodes PL10A, PL10B, PL11B, PL20A, and PL20B. The inductor L6 in FIG. 2 includes the via V50. The inductor L7 in FIG. 2 includes the via VG1. Meanwhile, the capacitor C1 in FIG. 2 includes the capacitor electrodes PC1 and PC14, and of the ground electrode PG1.

The output terminal T2 is connected to the capacitor electrode PC2 provided on the dielectric layer LY8 by a via V20. The capacitor electrode PC2 is connected to the capacitor electrode PC15 provided the dielectric layer LY6 by the via V21. The capacitor electrode PC15 is connected to one end of the plate electrode PL30A provided on the dielectric layer LY4 by the via V22.

Another end of the plate electrode PL30A is connected to the end portion PL243B of the plate electrode PL20B and to one end of the plate electrode PL31B by the via V26. The vias V23, V24, and V25 are sequentially connected from one end to another end along a line of the plate electrode PL30A. The via V23 is connected to one end of PL30B, and the via V24 is connected to another end of PL30B. The via V25 is connected to another end of the plate electrode PL31B.

The via V27 is connected to one end of the plate electrode PL22A. The via V28 is connected to another end of the plate electrode PL22A. The vias V27 and V28 are sequentially connected along the line of the plate electrode PL20B.

The plate electrodes PL30B and PL31B are disposed so as to overlap the plate electrode PL30A in plan view in the direction of lamination. The plate electrode PL22A is disposed so as to overlap the plate electrode PL20B in plan view in the direction of lamination. The plate electrode PL20B is connected to the ground electrode PG1 provided on the dielectric layer LY7 by the via V50. The ground electrode PG1 is connected to the ground terminal GND provided the dielectric layer LY9 by the via VG1.

The inductor L2 in FIG. 2 includes the vias V21, V22, V23, V24, V25, V26, V27, and V28, and the plate electrodes PL30A, PL30B, PL31B, PL22A, and PL20B. The inductor L6 in FIG. 2 includes the via V50. The inductor L7 in FIG. 2 includes the via VG1. Meanwhile, the capacitor C2 in FIG. 2 includes the capacitor electrodes PC2 and PC15, and the ground electrode PG1.

The ground electrode PG2 located adjacent in the positive direction of the y axis to the capacitor electrodes PC1 and PC2 is provided the dielectric layer LY8. The ground electrode PG2 is connected to the ground terminals GND at the dielectric layer LY9 by the vias VG2, VG3, and VG4. The ground electrode PG2 partially overlaps the capacitor electrode PC12 provided on the adjacent dielectric layer LY7 in plan view in the direction of lamination. The capacitor C5 in FIG. 2 includes the ground electrode PG2 and the capacitor electrode PC12.

The capacitor electrode PC12 is connected to the end portion PL242B of the plate electrode PL20B provided on the dielectric layer LY3 by the via V30. The plate electrode PL20B is connected to one end portion of the plate electrode PL21A provided on the dielectric layer LY2 by the via V31. The plate electrode PL20B is connected to another end portion of the plate electrode PL21A provided on the dielectric layer LY2 by the via V32. The plate electrode PL21A is disposed so as to overlap the plate electrode PL20B in plan view in the direction of lamination.

One end of the extending portion 213B of the plate electrode PL20B is connected to one end of the plate electrode PL24A provided on the dielectric layer LY2 by the via V51. Another end of the extending portion 213B of the plate electrode PL20B is connected to another end of the plate electrode PL24A provided on the dielectric layer LY2 by the via V52. Meanwhile, the one end of the extending portion 213B of the plate electrode PL20B is connected to the ground electrode PG1 provided on the dielectric layer LY7 by the via V50. The ground electrode PG1 is connected to the ground terminal GND provided on the dielectric layer LY9 by the via VG1.

The inductor L3 in FIG. 2 includes the vias V30, V31, and V32, and the plate electrodes PL21A and PL20B. The inductor L8 in FIG. 2 includes the vias VG2, VG3, and VG4. The inductor L5 in FIG. 2 includes the vias V52 and V51, and the plate electrodes PL24A and PL20B. The inductor L6 in FIG. 2 includes the via V50. The inductor L7 in FIG. 2 includes the via VG1. Meanwhile, the capacitor C5 in FIG. 2 includes the ground electrode PG2 and the capacitor electrode PC12.

The ground electrode PG2 partially overlaps the capacitor electrode PC13 provided on the adjacent dielectric layer LY7 in plan view in the direction of lamination. The capacitor C6 in FIG. 2 includes the ground electrode PG2 and the capacitor electrode PC13.

The capacitor electrode PC13 is connected to the end portion PL244B of the plate electrode PL20B provided on the dielectric layer LY3 by the via V40. The plate electrode PL20B is connected to one end portion of the plate electrode PL23A provided on the dielectric layer LY2 by the via V41. The plate electrode PL20B is connected to another end portion of the plate electrode PL23A provided on the dielectric layer LY2 by the via V42. The plate electrode PL23A is disposed so as to overlap the plate electrode PL20B in plan view in the direction of lamination. The inductor L4 in FIG. 2 includes the vias V40, V41, and V42, and of the plate electrodes PL23A and PL20B. The inductor L8 in FIG. 2 includes the vias VG2, VG3, and VG4. The inductor L5 in FIG. 2 includes the vias V52 and V51, and the plate electrodes PL24A and PL20B. The inductor L6 in FIG. 2 includes the via V50. The inductor L7 in FIG. 2 includes the via VG1. Meanwhile, the capacitor C6 in FIG. 2 includes the ground electrode PG2 and the capacitor electrode PC13.

In the meantime, the capacitor electrode PC12 partially overlaps the capacitor electrode PC14 as well, which is provided on the dielectric layer LY6 in plan view in the direction of lamination. The capacitor C3 in FIG. 2 includes the capacitor electrodes PC12 and PC14. The capacitor electrode PC13 partially overlaps the capacitor electrode PC15 as well, which is provided on the dielectric layer LY6 in plan view in the direction of lamination. The capacitor C4 in FIG. 2 includes the capacitor electrodes PC13 and PC15. The resonator RC1 is field-coupled to the resonator RC3 by the capacitor C3, and the resonator RC2 is field-coupled to the resonator RC4 by the capacitor C4.

The capacitor electrode PC11 located adjacent in the positive direction of the y axis to the ground electrode PG1 is provided on the dielectric layer LY7. The capacitor electrode PC11 partially overlaps the capacitor electrodes PC14 and PC15 provided on the dielectric layer LY6 in plan view in the direction of lamination. The capacitor C7 in FIG. 2 includes the capacitor electrodes PC11, PC14, and PC15. The resonator RC1 is field-coupled to the resonator RC2 by the capacitor C7.

The above-described filter device 100 has a possibility of causing lamination misalignment in which the respective dielectric layers are misaligned in the x-axis direction and/or the y-axis direction in the course of laminating and pressure bonding the multiple dielectric layers. An inside diameter of a coil defined by the inductors overlapping in the direction of lamination varies in the case where the lamination misalignment occurs in the electrodes that define the inductors. Accordingly, an inductance value may be changed from a designed value in some cases. Such a change in inductance value may adversely affect filter characteristics including deviations of a pass band width, a center frequency, and the like, for example, of the filter.

Regarding the plate electrode PL20A and the plate electrode PL20B overlapping in the direction of lamination in the filter device 100 of the present example embodiment, the length in the x axis direction of the extending portion PL201A is smaller than the length in the x axis direction of the extending portion PL201B. To put it another way in terms of the area, the area of the extending portion PL201A is smaller than the area of the extending portion PL201B.

Here, in the case of a filter device in which two plate electrodes overlapping in the direction of lamination have the same or substantially the same shape, changes in characteristics of an inductor in the case of an occurrence of lamination misalignment in the x axis direction being a long side direction become greater than those in the case of an occurrence of lamination misalignment in the y axis direction being a short side direction. This is due to the following reasons. In the case where the two plate electrodes overlapping in the direction of lamination have the same or substantially the same shape, a change in inside diameter of the coil at a portion where the two plate electrodes overlap in the direction of lamination is greater in the case of an occurrence of lamination misalignment in the short side direction than that in the case of an occurrence of lamination misalignment in the long side direction. Accordingly, an electrode configuration only needs to be such a shape that can reduce an influence brought about when the extending portion that extends in the x axis direction being the long side direction is misaligned in the y axis direction being the short side direction.

In consideration of the changes in filter characteristics due to the lamination misalignment, the filter device 100 of the Example Embodiment 1 provides the plate electrodes that define the inductor with the distinctive shapes of the extending portions that extend in the x axis direction being the long side direction. As described above, regarding the two plate electrodes of the filter device 100 overlapping in the direction of lamination, the length in the long side direction (the x axis direction) of the extending portion of one of the plate electrodes disposed in the x axis direction being the long side direction is set smaller than the length in the long side direction (the x axis direction) of the extending portion of the other plate electrode. To put it another way in terms of the area, the area of the extending portion of the one plate electrode disposed in the x axis direction being the long side direction is set smaller than the area of the extending portion of the other plate electrode.

The filter device 100 provides a difference between the lengths in the long side direction of the extending portions (which can also be translated into the areas) having a large influence on the changes in characteristics even in case of the occurrence of lamination misalignment that may lead to displacement of positions of the two plate electrodes overlapping in the direction of lamination. Thus, the filter device 100 can reduce or prevent the change in inside diameter of the coil including the electrodes defining and functioning as the inductor, thus reducing the changes in filter characteristics.

Using the configuration to reduce the area of the portion having the large influence on the changes in characteristics, the filter device 100 can reduce or prevent the change in inside diameter of the coil including the electrodes defining and functioning as the inductor, and reduce the changes in filter characteristics even in case of the occurrence of lamination misalignment that may lead to displacement of positions between the plate electrode PL20A and the plate electrode PL20B. The advantageous effects are exerted similarly in cases of displacement of positions between the plate electrode PL21A and the plate electrode PL20B, displacement of positions between the plate electrode PL22A and the plate electrode PL20B, and displacement of positions between the plate electrode PL23A and the plate electrode PL20B as well.

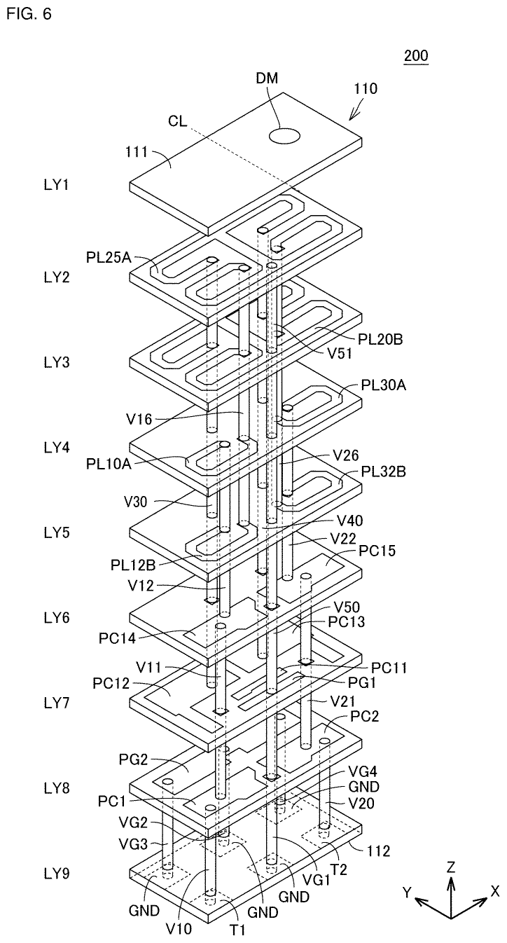

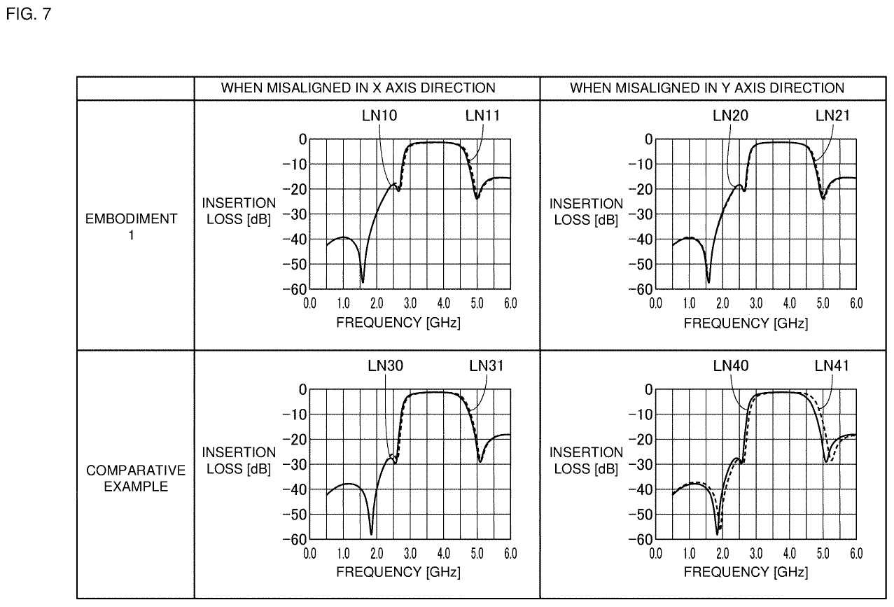

Next, the characteristics of the plate electrodes will be described while comparing with those of a comparative example with reference to FIGS. 6 and 7. FIG. 6 is an exploded perspective view showing an example of a lamination structure of a filter device 200 of Comparative Example. FIG. 7 illustrates diagrams for explaining changes in characteristics of Example Embodiment 1 and Comparative Example.

In comparison with the filter device 100 of Example Embodiment 1 of FIG. 4, the filter device 200 of Comparative Example of FIG. 6 has different shapes of the plate electrodes and the vias at the dielectric layers LY2 to LY5. Specifically, the electrodes in the same or substantially the same shape are provided into two layers in the dielectric layers LY2 and LY3 as well as in the dielectric layers LY4 and LY5. A description will be provided of the filter device 200 of FIG. 6 while mainly focusing on different points from those of the filter device 100 of FIG. 4.

The plate electrode PL20B provided on the dielectric layer LY3 has the same or substantially the same shape as that of the plate electrode PL20B in the filter device 100 of Example Embodiment 1. The plate electrode PL20B is configured to include four annular belt-shaped electrodes with a winding axis in the z axis direction, and has a line-symmetric shape which is symmetric about the extending portion PL213B as a whole. A plate electrode 25A having the same or substantially the same shape as that of the plate electrode PL20B is provided on the dielectric layer LY2.

The plate electrode PL10A provided on the dielectric layer LY4 has the same or substantially the same shape as that of the plate electrode PL10A in the filter device 100 of Example Embodiment 1. The plate electrode PL10A is a belt-shaped electrode wound about the z axis and substantially has a J shape, a U shape, or a C shape, for example. A plate electrode PL12B having the same or substantially the same shape as that of the plate electrode PL10A is provided on the dielectric layer LY5.

One end portion of the plate electrode PL10A provided on the dielectric layer LY4 is connected to one end portion of the plate electrode PL12B provided the dielectric layer LY5 by the via V12. Another end portion of the plate electrode PL10A is connected to another end portion of the plate electrode PL12B provided on the dielectric layer LY5 by the via V16.

Meanwhile, the other end portion of the plate electrode PL10A is connected to one end portion of the plate electrode PL20B provided on the dielectric layer LY3 by the via V16. The plate electrode PL20B is connected to one end portion of the plate electrode PL25A provided on the dielectric layer LY2 by the via V16.

One end portion of the plate electrode PL30A provided on the dielectric layer LY4 is connected to one end portion of a plate electrode PL32B provided the dielectric layer LY5 by the via V22. Another end portion of the plate electrode PL30A is connected to another end portion of the plate electrode PL32B provided on the dielectric layer LY5 by the via V26.

Meanwhile, the other end portion of the plate electrode PL30A is connected to the one end portion of the plate electrode PL20B provided on the dielectric layer LY3 by the via V26. The plate electrode PL20B is connected to the one end portion of the plate electrode PL25A provided on the dielectric layer LY2 by the via V26.

The plate electrode PL25A provided on the dielectric layer LY2 is connected to the end portion PL241B of the plate electrode PL20B provided on the dielectric layer LY3 by the via V16. The plate electrode PL25A is connected to the end portion PL243B of the plate electrode PL20B provided on the dielectric layer LY3 by the via V26. The plate electrode PL25A is connected to the end portion PL242B of the plate electrode PL20B provided on the dielectric layer LY3 by the via V30. The plate electrode PL25A is connected to the end portion PL244B of the plate electrode PL20B provided on the dielectric layer LY3 by the via V40. The plate electrode PL25A is connected to one end portion of the extending portion PL213B of the plate electrode PL20B provided on the dielectric layer LY3 by the via V50.

As described above, in the filter device 200, the electrode configurations of the plate electrode PL25A and the plate electrode PL20B overlapping in the direction of lamination have the same or substantially the same shape unlike those in the filter device 100. Meanwhile, in the filter device 200, the electrode configurations of the plate electrode PL10A and the plate electrode PL12B overlapping in the direction of lamination have the same or substantially the same shape, and the electrode configurations of the plate electrode PL30A and the plate electrode PL32B overlapping in the direction of lamination have the same or substantially the same shape. Here, the shapes of every two plate electrodes may be the same. Changes in characteristics of the Example Embodiment 1 and the Comparative Example will be described by using FIG. 7.

FIG. 7 illustrates how simulations of the filter characteristics were conducted in the case of the occurrence of lamination misalignment in the x axis direction being the long side direction and in the case of the occurrence of lamination misalignment in the y axis direction being the short side direction regarding the filter device 100 of Example Embodiment 1 and the filter device 200 of Comparative Example. In each graph in FIG. 7, the horizontal axis indicates a frequency and the vertical axis indicates an insertion loss. In FIG. 7, solid lines LN10, LN20, LN30, and LN40 each represent the case of non-occurrence of lamination misalignment while dashed lines LN11, LN21, LN31, and LN41 each represent the case of occurrence of lamination misalignment. Amounts of the lamination misalignment in the x axis direction and in the y axis direction are equal or substantially equal.

As shown in FIG. 7, in the case of the occurrence of lamination misalignment in the x axis direction, changes s in insertion loss are very small in both of the filter device 100 of Example Embodiment 1 and the filter device 200 of Comparative Example. On the other hand, in the case of the occurrence of lamination misalignment in the y axis direction, a change in insertion loss is very small in the filter device 100 of Example Embodiment 1 whereas a change in insertion loss in the filter device 200 of Comparative Example is larger than that of the filter device 100. As shown in FIG. 7, the dashed line LN41 is deviated in a direction toward a higher frequency from the solid line LN40 on the whole.

Here, a trade-off relationship is present between the improvement in the Q factor and the reduction of the changes in filter characteristics due to lamination misalignment. That is to say, resistance values may be reduced by increasing the areas of the plate electrodes (parallel portions) overlapping in the direction of lamination in order to improve the Q factor. However, the change in inside diameter of the coil, which includes the electrodes overlapping in the direction of lamination and defining and functioning as the inductor, is increased in the case of the occurrence of lamination misalignment by increasing the areas of the plate electrodes, thus resulting in increases in changes in filter characteristics. The filter device 100 includes the electrode configurations in consideration of the improvement in the Q factor and the reduction of the changes in filter characteristics.

Here, regarding the two plate electrodes in the filter device 100 overlapping in the direction of lamination, the area of the extending portion of one of the plate electrodes disposed in the y axis direction being the short side direction is nearly equal or substantially equal to the area of the extending portion of the other plate electrode. As shown in FIG. 7, this is because even if lamination misalignment in the x axis direction being the long side direction occurs in the extending portion that extends in the short side its influence on the changes in direction, characteristics is very small. The areas of the extending portions in the short side direction may be equal or substantially equal.

A position in the filter device 100 where an extending portion in the long side direction is connected to an extending portion in the short side direction will be referred to as a corner portion. As shown in FIGS. 5A to 5D, regarding the plate electrodes in the filter device 100, the areas of the corner portions located adjacent to each other are equal or substantially equal, because the corner portion is a position of concentration of a current and is therefore not preferable to change the shape (the width) of the plate electrode. Here, the areas of the corner portions may be equal or substantially equal.

Now, relationships among the multiple plate electrodes in the direction of lamination will be described with reference to FIG. 4. Regarding the dielectric layers LY2 to LY5 arranged in the direction of lamination of the multilayer body, the plate electrodes are disposed in the order of PL20A, PL20B, PL10A, and PL10B as shown in FIG. 4. Meanwhile, regarding the dielectric layers LY2 to LY5, the plate electrodes are disposed in the order of PL22A, PL20B, PL30A, and PL30B so as to be line-symmetric about the imaginary line CL.

The plate electrodes PL20A, PL20B, PL10A, and PL10B partially overlap one another in plan view in the direction of lamination of the multilayer body. Meanwhile, the plate electrodes PL22A, PL20B, PL30A, and PL30B partially overlap one another in plan view in the direction of lamination of the multilayer body. In the above-described plate electrodes, the area of the extending portion in the x axis direction of the plate electrode PL20B at the dielectric layer LY3 is larger than the area of the extending portion in the x axis direction of the plate electrode PL20A at the dielectric layer LY2, and the area of the extending portion in the x axis direction of the plate electrode PL10A at the dielectric layer LY4 is larger than the area of the extending portion in the x axis direction of the plate electrode PL10B at the dielectric layer LY5.

That is to say, regarding the pair of plate electrodes PL20A and PL20B and the pair of plate electrodes PL10A and PL10B disposed in the direction of lamination, the areas of the extending portions in the x axis direction of the plate electrode PL20B at the dielectric layer LY3 and of the plate electrode PL10A at the dielectric layer LY4 which are located at positions opposed to each other are larger than the areas of the extending portions in the x axis direction of the plate electrode PL20A at the dielectric layer LY2 and of the plate electrode PL11B at the dielectric layer LY5 which are not located at positions opposed to each other. Accordingly, in the case where the areas of the pair of plate electrodes are large, it is possible to reduce a resistance value of a current pathway as compared to the case where the areas of the pair of plate electrodes located at the positions opposed to each other are small.

In the filter device 100 of Example Embodiment 1, the length in the long side direction (the x axis direction) of the extending portion of one of the plate electrodes disposed in the x axis direction being the long side direction is smaller than the length in the long side direction (the x axis direction) of the extending portion of the other plate electrode. To put it another way in terms of the area, the area of the extending portion of the one plate electrode disposed in the x axis direction being the long side direction is smaller than the area of the extending portion of the other plate electrode. By setting the area of the extending portion of the one plate electrode smaller than the area of the extending portion of the other plate electrode, it is possible to reduce or prevent the change in inside diameter of the coil including the electrodes defining and functioning as the inductor, and to reduce the changes in filter characteristics even in the case where the occurrence of lamination misalignment leads to displacement of positions between the plate electrodes disposed in the direction of lamination.

### Example Embodiment 2

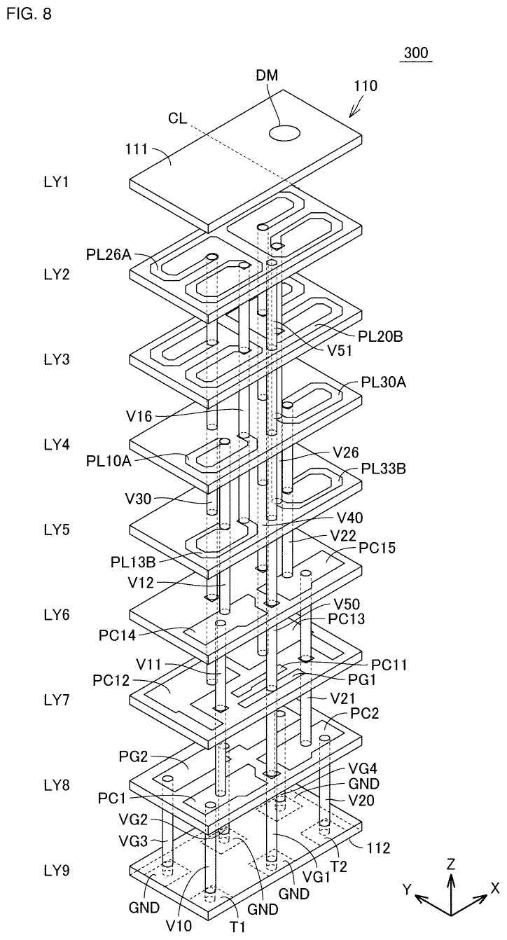

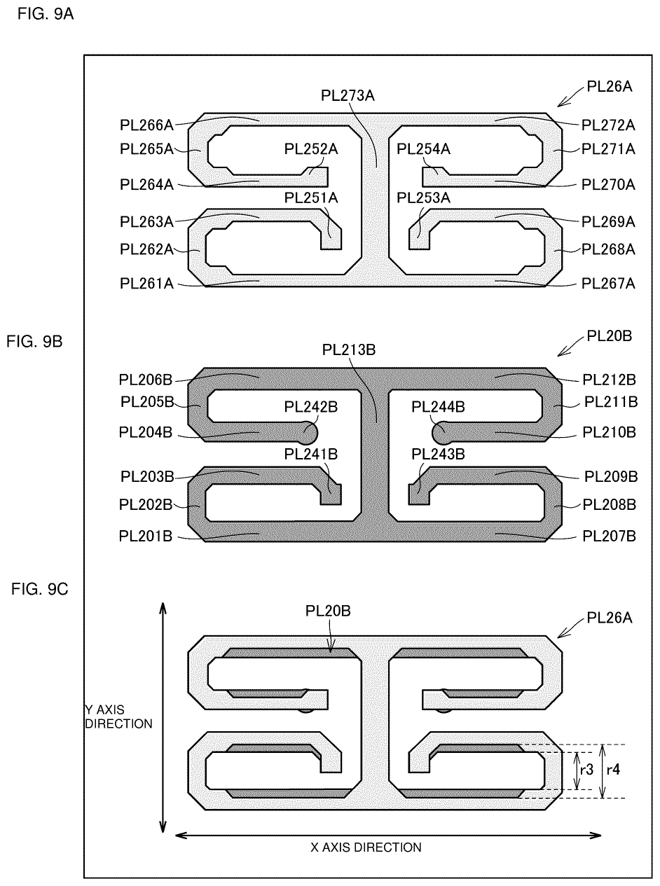

Next, regarding a filter device 300 of Example Embodiment 2 of the present invention, variations of the electrode configurations will be described by using FIGS. 8 to 9C. The electrode configurations of the filter device 300 in Example Embodiment 2 have such electrode configurations that enable reduction of changes in filter characteristics by using different electrode configurations from those of the filter device 100 of the Example Embodiment 1. FIG. 8 is an exploded perspective view showing an example of a lamination structure of the filter device 300 of Example Embodiment 2. FIGS. 9A to 9C are diagrams for explaining the electrode configurations of Example Embodiment 2.

As compared to the filter device 100 of Example Embodiment 1 in FIG. 4, the filter device 300 of Example Embodiment 2 in FIG. 8 has different shapes and layouts of the plate electrodes and of the vias at the dielectric layers LY2 to LY5. The filter device 300 of FIG. 8 will be described while mainly focusing on different points from those in the filter device 100 of FIG. 4. The shapes and layouts of the vias are the same or substantially the same as those in the filter device 200 of the Comparative Example in FIG. 6, and a description thereof will be omitted.

The plate electrode PL20B provided on the dielectric layer LY3 has the same or substantially the same shape as that of the plate electrode PL20B in the filter device 100 of Example Embodiment 1. The plate electrode PL20B is configured to include four annular belt-shaped electrodes with a winding axis in the z axis direction, and has the line-symmetric shape which is symmetric about the extending portion PL213B. Although a plate electrode PL26A provided on the dielectric layer LY2 has broadly the same shape as that of the plate electrode PL20B, the shape of the electrode is different in that the electrode at the portion extending in the x axis direction being the long side direction is thinner than the portion extending in the x axis direction of the plate electrode PL20B disposed at the dielectric layer LY3.

A plate electrode PL13B provided on the dielectric layer LY5 is a belt-shaped electrode wound about the z axis and substantially has a J shape, a U shape, or a C shape, for example. The electrode configuration of the plate electrode PL13B is different in that the electrode at the portion extending in the x axis direction being the long side direction is thinner than the portion extending in the x axis direction of the plate electrode PL10A disposed at the dielectric layer LY4.

A plate electrode PL33B provided on the dielectric layer LY5 is a belt-shaped electrode wound about the z axis and substantially has a J shape, a U shape, or a C shape, for example. The electrode configuration of the plate electrode PL33B is different in that the electrode at the portion extending in the x axis direction being the long side direction is thinner than the portion extending in the x axis direction of the plate electrode PL30A disposed at the dielectric layer LY4.

As described above, the filter device 300 includes the different shapes of the two plate electrodes overlapping in the direction of lamination as with those in the filter device 100. The plate electrodes of the filter device 300 are different in that widths of the extending portions are thin unlike the plate electrodes of the filter device 100 in which the lengths of the extending portions are small. Here, as compared to the filter device 200 of the Comparative Example, the filter device 300 has the same or substantially the same electrode configurations other than those at the dielectric layers LY2 and LY5.

### Electrode Configuration

The multilayer body of the filter device 300 has a rectangular or substantially rectangular shape including a long side and a short side in plan view in the direction of lamination. A description will be provided of the electrodes of the inductor among the electrodes to be provided on the respective dielectric layers. The electrode configurations of the plate electrode PL26A provided on the dielectric layer LY2 and the plate electrode PL20B provided on the dielectric layer LY3 among the plate electrodes shown in FIG. 8 will be described in FIGS. 9A to 9C.

FIG. 9A is a diagram of the plate electrode PL26A in plan view in the z axis direction. FIG. 9B is a diagram of the plate electrode PL20B in plan view in the z axis direction. FIG. 9C is a diagram of the dielectric layer LY2 and the dielectric layer LY3 in plan view in the z axis direction.

As shown in FIG. 9A, the plate electrode PL26A includes an extending portion PL273A that extends in the y axis direction. An extending portion PL261A extends in the negative direction of the x axis from one end of the extending portion PL273A, and an extending portion PL267A extends in the positive direction of the x axis therefrom. Meanwhile, an extending portion PL266A extends in the negative direction of the x axis from another end of the extending portion PL273A, and an extending portion PL272A extends in the positive direction of the x axis therefrom.

An end portion in the negative direction of the x axis of the extending portion PL261A is connected to one end of an extending portion PL262A that extends in the y axis direction. Another end of the extending portion PL262A is connected to an end portion in the negative direction of x axis of an extending portion PL263A that extends in the x axis direction. An end portion PL251A in the positive direction of the x axis of the extending portion PL263A is formed into an open end. An end portion in the positive direction of the x axis of the extending portion PL267A is connected to one end of an extending portion PL268A that extends in the y axis direction. Another end of the extending portion PL268A is connected to an end portion in the positive direction of the x axis of an extending portion PL269A that extends in the x axis direction. An end portion PL253A in the negative direction of the x axis of the extending portion PL269A is an open end.

An end portion in the negative direction of the x axis of an extending portion PL264A is connected to one end of an extending portion PL265A extending in the y axis direction. Another end of the extending portion PL265A is connected to an end portion in the negative direction of the x axis of the extending portion PL264A that extends in the x axis direction. An end portion PL252A in the positive direction of the x axis of the extending portion PL264A is an open end. An end portion in the positive direction of the x axis of the extending portion PL272A is connected to one end of an extending portion PL271A extending in the y axis direction. Another end of the extending portion PL271A is connected to an end portion in the positive direction of the x axis of an extending portion PL270A extending in the x axis direction. An end portion PL254A in the negative direction of the x axis of the extending portion PL270A is an open end.

The plate electrode PL26A is configured to include four annular belt-shaped electrodes with a winding axis in the z axis direction, and has a line-symmetric shape which is symmetric about the extending portion PL273A. The shape of the plate electrode PL20B in FIG. 9B is the same or substantially the same as the shape of the above-described plate electrode PL20B in FIG. 5B. Accordingly, the explanation thereof will not be repeated.

Regarding the plate electrode PL26A and the plate electrode PL20B overlapping in the direction of lamination, a length in the y axis direction of the extending portion PL261A is smaller than a length in the y axis direction of the extending portion PL201B. To put it another way in terms of the area, the area of the extending portion PL261A is smaller than the area of the extending portion PL201B. The above-described relationship is the same or substantially the same as a relationship between the extending portion PL263A and the extending portion PL203B, a relation between the extending portion PL264A and the extending portion PL204B, a relationship between the extending portion PL266A and the extending portion PL206B, a relationship between the extending portion PL267A and the extending portion PL207B, a relationship between the extending portion PL269A and the extending portion PL209B, a relationship between the extending portion PL270A and the extending portion PL210B, and a relationship between the extending portion PL272A and the extending portion PL212B as well.

Here, the plate electrode PL26A has the line-symmetric shape which is symmetric about the extending portion PL273A. In the above-described structure, a distance r4 in the y axis direction between the extending portion PL269A and the extending portion PL269A is longer than a distance r3 in the y axis direction between the extending portion PL209B and the extending portion PL209B. The above-described relationship is the same or substantially the same as a relationship of a distance between the extending portion PL261A and the extending portion PL262A with a distance between the extending portion PL201B and the extending portion PL203B, a relationship of a distance between the extending portion PL264A and the extending portion PL266A with a distance between the extending portion PL204B and the extending portion PL206B, and a relationship of a distance between the extending portion PL270A and the extending portion PL272A with a distance between the extending portion PL210B and the extending portion PL212B as well.

In consideration of the changes in filter characteristics due to lamination misalignment, the filter device 300 of Example Embodiment 2 provides the plate electrodes that define the inductor with the distinctive shapes of the extending portions that extend in the x axis direction being the long side direction. As described earlier, regarding the two plate electrodes of the filter device 300 overlapping in the direction of lamination, the length in the short side direction (the y axis direction) of the extending portion of one of the plate electrodes disposed in the x axis direction being the long side direction is smaller than the length in the short side direction (the y axis direction) of the extending portion of the other plate electrode. To put it another way in terms of the area, the area of the extending portion of the one plate electrode disposed in the x axis direction being the long side direction is smaller than the area of the extending portion of the other plate electrode.

To put it still another way in terms of the distance, the distance between one set of the extending portions disposed at the positions opposed to each other in the y axis direction is longer than the distance between another set of the extending portions disposed at the positions opposed to each other in the y axis direction.

Here, regarding plate electrodes that define an inductor, an inductance value mainly depends on an inside diameter of a coil including the plate electrodes in general. In the filter device 300, only the shapes on the inside diameter side of the two plate electrodes overlapping in the direction of lamination are changed but shapes on the outside diameter side are not changed. To be more precise, the plate electrode PL26A at the dielectric layer LY2 has the shape provided by scraping off the extending portions PL267A and PL269A on the inside diameter side each by (r4-r3)/2 relative to the plate electrode PL20B at the dielectric layer LY3. Accordingly, even in a case of the occurrence of lamination misalignment that causes the positions of the two plate electrodes overlapping in the direction of lamination to deviate in the y axis direction, the filter device 300 can avoid the change in inside diameter within the range of the scraped portions. Thus, the change in inductance value can be reduced or prevented. In this way, it is possible to reduce changes in filter characteristics.

### Modified Example 1

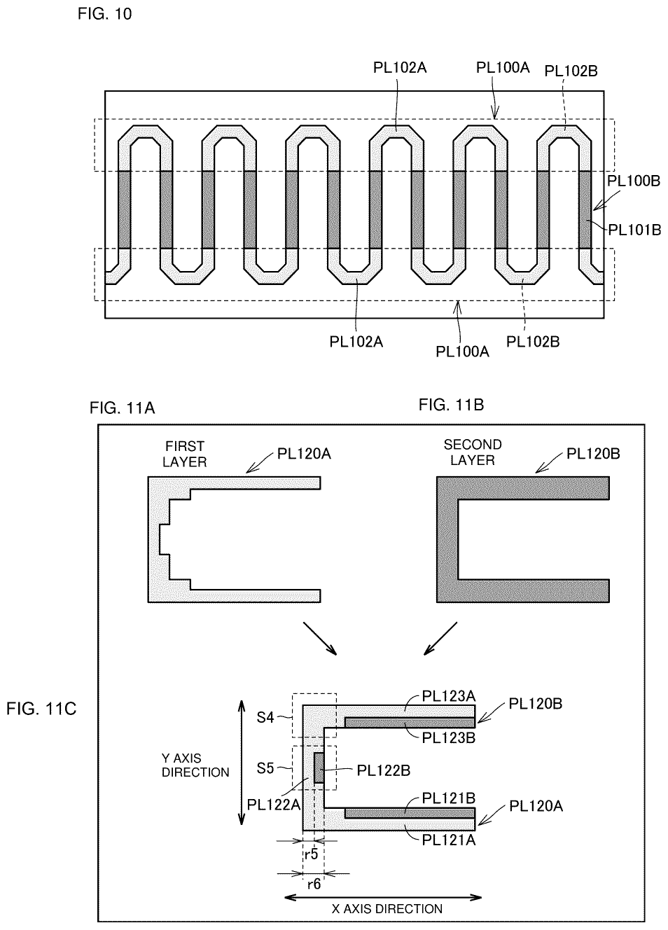

Next, electrode forms of Modified Example 1 of an example embodiment of the present invention will be described. The shapes of the extending portions of the plate electrodes are different in Modified Example 1. The electrodes of Modified Example 1 represent partially extracted extending portions of the plate electrodes that define the inductor. FIG. 10 is a diagram for explaining the electrode configurations of Modified Example 1. The electrodes of Modified Example 1 include plate electrodes PL100A and a plate electrode PL100B which are disposed in the direction of lamination.

The plate electrodes PL100A are electrodes disposed in regions surrounded by dashed lines in FIG. 10. The plate electrodes PL100A and the plate electrode PL100B are disposed so as to overlap in the case of plan view in the direction of lamination of the multilayer body, and are connected in the direction of lamination by vias so as to form parallel or substantially parallel lines. The plate electrode PL100B has, for example, a meandering shape in which U-shaped bent portions PL102B and straight portions PL101B are alternately disposed. The plate electrodes PL100A include only U-shaped bent portions PL102A that correspond to the bent portions PL102B in the plate electrode PL100B.

In the electrodes having the meandering shape as shown in Modified Example 1 of FIG. 10 as well, the plate electrodes PL100A and the plate electrode PL100B overlapping in plan view in the direction of lamination of the multilayer body are designed such that the area of the straight portion of each plate electrode PL100A is smaller than the area of the plate electrode PL100B. Accordingly, even in case of the occurrence of lamination misalignment that causes deviation of the positions of the two plate electrodes overlapping in the direction of lamination, it is possible to reduce or prevent the change in inside diameter of the coil including the electrodes defining and functioning as the inductor, and thus to reduce changes in filter characteristics.

### Modified Example 2

Next, electrode forms of Modified Example 2 of an example embodiment of the present invention will be described. In the electrodes of Modified Example 2, the shapes in the y axis direction of the extending portions are different. The electrodes of Modified Example 2 represent an extracted portion that includes a corner portion which is a position where an extending portion in the long side direction is connected to an extending portion in the short side direction. FIGS. 11A to 11C are diagrams for explaining electrode configurations of Modified Example 2. The electrodes in FIGS. 11A to 11C are diagrams corresponding to portions of the plate electrodes PL20A and PL20B of Example Embodiment 1. The electrodes of Modified Example 2 include a pair of plate electrodes PL120A and plate electrodes PL120B, which are disposed in the direction of lamination.

As shown in FIG. 11A, the plate electrode PL120A defining and functioning as a first layer has such a shape that an inner side portion is partially scraped off so as to provide the electrode with stair-shaped steps. As shown in FIG. 11B, the plate electrode PL120B defining and functioning as a second layer has a U-shape with a uniform electrode width. A layout of the electrodes as shown in FIG. 11C is obtained by superimposing the plate electrodes PL120A and the plate electrodes PL120B in the direction of lamination.

The plate electrode PL120A includes extending portions PL121A and PL123A that extend in the x axis direction, and an extending portion PL122A that extends in the y axis direction. The plate electrode PL120B includes extending portions PL121B and PL123B that extend in the x axis direction, and an extending portion PL122B that extends in the y axis direction.

Here, regarding the two plate electrodes overlapping in the direction of lamination, the area of the extending portion PL121A extending in the x axis direction is smaller than the area of the extending portion PL121B. The above-described relationship is the same or substantially the same as a relationship between the extending portion PL123A extending in the x axis direction and the extending portion PL123B as well. Meanwhile, regarding the two plate electrodes overlapping in the direction of lamination, the area of the extending portion PL122A extending in the y axis direction is smaller than the area of the extending portion PL122B.

The shapes of the electrodes will be described in detail. A region S4 surrounded by a dashed line in FIG. 11C indicates the corner portion of the electrodes overlapping in the direction of lamination. A region S5 surrounded by another dashed line in FIG. 11C indicates a central portion in the y axis direction of the electrodes overlapping in the direction of lamination. As shown in FIG. 11C, the areas of the corner portions in the region S4 are equal or substantially equal between the two plate electrodes 120A and 120B overlapping in the direction of lamination. On the other hand, regarding the two plate electrodes overlapping in the direction of lamination, the areas of the central portions in the y axis direction in the region S5 are different between the plate electrode PL120A and the plate electrode PL120B. To be more precise, a width r5 in the x axis direction of the extending portion PL122A is smaller than a width r6 in the x axis direction of the extending portion PL1212B. Accordingly, the area at the central portion in the y axis direction indicated in the region S5 of the plate electrode PL120A is smaller than that of the plate electrode PL120B.

As shown in FIGS. 11A to 11C, regarding the electrodes of Modified Example 2, the areas of the corner portions in the region S4 of the first layer and the second layer are equal or substantially equal whereas the area of the central portion in the y axis direction in the region S5 of the first layer is smaller than that of the second layer. As described above, the electrodes of Modified Example 2 provide the different areas at the central portions between the first layer and the second layer while providing the equal or substantially equal areas at the corner portions on these layers located at the position to change a direction of a flow of the current. Accordingly, it is possible to avoid a change in shape (width) of each corner portion being the position of concentration of the current, and to reduce or prevent a change in inside diameter of the coil including the electrodes defining and functioning as the inductor even in case of the occurrence of lamination misalignment in the x axis direction that may lead to misalignment of the positions of the two plate electrodes overlapping in the direction of lamination. Thus, changes in filter characteristics can be reduced.

Regarding the LC resonator including the inductor and the capacitor and being configured to transmit a signal from the input terminal to the output terminal, Example Embodiment 1 has shown the configuration to provide the resonators in four tiers. However, the number of tiers in the LC resonator (the number of the resonators) may be any suitable number.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A filter device comprising:
a multilayer body including a plurality of dielectric layers;
an input terminal and an output terminal on an outer surface of the multilayer body; and
an LC resonator including an inductor and a capacitor and being configured to transmit a signal from the input terminal to the output terminal; wherein
the LC resonator includes a first plate electrode and a second plate electrode on dielectric layers of the plurality of dielectric layers different from each other and connected to each other by a via;
the first plate electrode and the second plate electrode define and function as the inductor;
the first plate electrode and the second plate electrode overlap at least partially in a plan view in a direction of lamination of the multilayer body;
the multilayer body has a rectangular or substantially rectangular shape including a long side and a short side in the plan view in the direction of lamination;
the first plate electrode includes:
a first extending portion extending in a first direction along a direction of the long side of the multilayer body; and
a second extending portion extending in a second direction along a direction of the short side of the multilayer body;
the second plate electrode includes:
a third extending portion extending in the first direction; and
a fourth extending portion extending in the second direction; and
an area of the first extending portion is smaller than an area of the third extending portion.

2. The filter device according to claim 1, wherein a length in the first direction of the first extending portion is smaller than a length in the first direction of the third extending portion.

3. The filter device according to claim 1, wherein a length in the second direction of the first extending portion is smaller than a length in the second direction of the third extending portion.

4. The filter device according to claim 3, wherein
the first extending portion includes a first portion and a second portion opposed to each other in the second direction;
the third extending portion includes a third portion and a fourth portion opposed to each other in the second direction;
one end of the second extending portion is connected to the first portion and another end of the second extending portion is connected to the second portion;
one end of the fourth extending portion is connected to the third portion and another end of the fourth extending portion is connected to the fourth portion; and
a distance in the second direction between the first portion and the third portion is longer than a distance in the second direction between the second portion and the fourth portion.

5. The filter device according to claim 1, wherein an area of the second extending portion is equal to or substantially equal to an area of the fourth extending portion.

6. The filter device according to claim 1, wherein an area of the second extending portion is smaller than an area of the fourth extending portion.

7. The filter device according to claim 1, wherein
the first extending portion is connected to the second extending portion at a first corner portion and the third extending portion is connected to the fourth extending portion at a second corner portion; and
an area of the first corner portion is equal to or substantially equal to an area of the second corner portion.

8. The filter device according to claim 1, wherein
the LC resonator further includes a third plate electrode and a fourth plate electrode on dielectric layers of the plurality of dielectric layers different from each other and connected to each other by a via;
the third plate electrode and the fourth plate electrode define and function as the inductor;
the first plate electrode, the second plate electrode, the third plate electrode, and the fourth plate electrode are arranged in order in the direction of lamination of the multilayer body;
the first plate electrode, the second plate electrode, the third plate electrode, and the fourth plate electrode overlap at least partially in plan view in the direction of lamination of the multilayer body,
the third plate electrode includes:
a fifth extending portion extending in the first direction; and
a sixth extending portion extending in the second direction;
the fourth plate electrode includes:
a seventh extending portion extending in the first direction; and
an eighth extending portion extending in the second direction; and
an area of the fifth extending portion is larger than an area of the seventh extending portion.

9. A filter device comprising:
a rectangular or substantially rectangular multilayer body including a plurality of dielectric layers;
an input terminal and an output terminal on an outer surface of the multilayer body; and
an LC resonator including an inductor and a capacitor and being configured to transmit a signal from the input terminal to the output terminal; wherein
the LC resonator includes a first plate electrode and a second plate electrode on different dielectric layers of the plurality of dielectric layers and connected to each other by a via;
the first plate electrode and the second plate electrode define and function as the inductor;
the first plate electrode and the second plate electrode overlap at least partially in plan view in a direction of lamination of the multilayer body;
the first plate electrode has a meandering shape including U-shaped bent portions and straight portions alternately provided; and
the second plate electrode includes only portions corresponding to the bent portions.

10. A communication apparatus comprising:
an antenna;
a high frequency front end circuit including the filter device according to claim 1;
a mixer;
a local oscillator;
a D/A converter; and
an RF circuit.

11. The communication apparatus according to claim 10, wherein a length in the first direction of the first extending portion is smaller than a length in the first direction of the third extending portion.

12. The communication apparatus according to claim 10, wherein a length in the second direction of the first extending portion is smaller than a length in the second direction of the third extending portion.

13. The communication apparatus according to claim 12, wherein
the first extending portion includes a first portion and a second portion opposed to each other in the second direction;
the third extending portion includes a third portion and a fourth portion opposed to each other in the second direction;
one end of the second extending portion is connected to the first portion and another end of the second extending portion is connected to the second portion;
one end of the fourth extending portion is connected to the third portion and another end of the fourth extending portion is connected to the fourth portion; and
a distance in the second direction between the first portion and the third portion is longer than a distance in the second direction between the second portion and the fourth portion.

14. The communication apparatus according to claim 10, wherein an area of the second extending portion is equal to or substantially equal to an area of the fourth extending portion.

15. The communication apparatus according to claim 10, wherein an area of the second extending portion is smaller than an area of the fourth extending portion.

16. The communication apparatus according to claim 10, wherein
the first extending portion is connected to the second extending portion at a first corner portion and the third extending portion is connected to the fourth extending portion at a second corner portion; and
an area of the first corner portion is equal to or substantially equal to an area of the second corner portion.

17. The communication apparatus according to claim 10, wherein
the LC resonator further includes a third plate electrode and a fourth plate electrode on dielectric layers of the plurality of dielectric layers different from each other and connected to each other by a via;
the third plate electrode and the fourth plate electrode define and function as the inductor;
the first plate electrode, the second plate electrode, the third plate electrode, and the fourth plate electrode are arranged in order in the direction of lamination of the multilayer body;
the first plate electrode, the second plate electrode, the third plate electrode, and the fourth plate electrode overlap at least partially in plan view in the direction of lamination of the multilayer bod;,
the third plate electrode includes:
a fifth extending portion extending in the first direction; and
a sixth extending portion extending in the second direction;
the fourth plate electrode includes:
a seventh extending portion extending in the first direction; and
an eighth extending portion extending in the second direction; and
an area of the fifth extending portion is larger than an area of the seventh extending portion.

18. A communication apparatus comprising:
an antenna;
a high frequency front end circuit including the filter device according to claim 9;
a mixer;
a local oscillator;
a D/A converter; and
an RF circuit.
